(19) United States
(12) Patent Application Publication
(10) Pub. No.: US 2026/0018453 A1
(43) Pub. Date: Jan. 15, 2026

(54) SUBSTRATE HOLDING DEVICE

(71) Applicant: NISSIN ION EQUIPMENT CO., LTD., Koka-city (JP)

(72) Inventors: Masatoshi ONODA, Koka-city (JP); Koyu UENO, Koka-city (JP); Daiki HIROSE, Koka-city (JP)

(21) Appl. No.: 19/261,843

(22) Filed: Jul. 7, 2025

(30) Foreign Application Priority Data
Jul. 9, 2024 (JP) 2024-110600

(51) Int. Cl. H01L 21/687

(52) U.S. Cl. CPC H01L 21/68728

(57) ABSTRACT

A substrate holding device can include a supporting base and supporting body oriented to receive a substrate and then reoriented to be processed by an ion beam. The supporting body can include support members that prevent and/or correct misalignment of the substrate to be processed.

### CROSS-REFERENCE TO RELATED APPLICATION

This application claims priority from Japanese Patent Application No. JP 2024-110600, filed in the Japanese Patent Office on Jul. 9, 2024, the disclosure of which being incorporated by reference herein in its entirety.

### BACKGROUND

### 1. Field

The disclosed embodiments relate to a substrate holding device that supports a substrate, and in particular to a substrate holding device used in a substrate processing apparatus, such as an ion implantation apparatus.

### 2. Description of Related Art

An ion implanter used in a semiconductor manufacturing process, or similar manufacturing processes generally includes a substrate holding device that supports a substrate in a processing chamber. An exemplary substrate holding device can include an electrostatic chuck that includes a mechanical clamp. The electrostatic chuck electrostatically adsorbs a substrate placed on a clamping surface and holds the substrate by mechanical clamping. Therefore, the electrostatic chuck can hold the substrate even if there is insufficient electrostatic attraction force.

The electrostatic chuck is typically rotatable to move between a horizontal position where the substrate is placed on the clamping surface and the clamping surface is horizontally oriented and a non-horizontal position where the substrate is placed on the clamping surface and is oriented towards an ion beam.

The electrostatic chuck can also hold the substrate with only the mechanical clamp even when the electrostatic chuck is in a non-horizontal position.

The electrostatic chuck of exemplary U.S. Pat. No. 8,941,968 is configured such that a plurality of mechanical clamps are disposed around a clamp surface, and each mechanical clamp performs a rotation operation about a predetermined rotation axis to push a substrate from the outside surface of the substrate, thereby holding the substrate at a predetermined position. However, since each mechanical clamp is configured to rotate in a direction in which the substrate is lifted, when the substrate is placed at a position deviated from a predetermined position on the clamp surface, it is assumed that the substrate is fixed in a state of being lifted by the mechanical clamp.

That is, in the electrostatic chuck of U.S. Pat. No. 8,941,968, when the substrate is placed at a position deviated from a predetermined position on the clamp surface, the substrate cannot be reliably held in the predetermined position.

### SUMMARY

According to an aspect of one or more embodiments of the disclosed subject matter, a substrate holding device can be configured to guide a substrate to a predetermined position and support the substrate at the predetermined position even when the substrate is placed at a position deviated from the predetermined position.

According to another aspect of one or more embodiments of the disclosed subject matter, a substrate holding device can include: a supporting base including a support surface configured to receive a substrate, the supporting base further configured to change from a loading posture to a processing posture by rotating the supporting base to change a direction of the support surface; and a plurality of support bodies, each support body having a support member and at least one contact surface, wherein each support body is configured to rotate about a predetermined rotation axis, causing each support body to move from an upper position where the contact surface is located above the support surface to a support position where the contact surface is located closer to the support surface than when in the upper position.

According to another aspect of one or more embodiments of the disclosed subject matter, a substrate holding device, can include: a supporting base including a support surface configured to receive a substrate, the supporting base further configured to change from a loading posture to a processing posture; and a plurality of support bodies, each support body having a support member having at least one contact surface, wherein the plurality of support bodies includes at least three contact surfaces separate from each other and located about a center of a substrate when the substrate is received on the supporting base, each of the plurality of support bodies is configured to rotate about a rotation axis, such that each of the plurality of support bodies is movable from an upper position where the at least one contact surface is located above the support surface to a support position where the at least one contact surface is located closer to the support surface than when in the upper position.

### BRIEF DESCRIPTION OF DRAWINGS

FIG. 1 is a schematic view of a substrate holding device and a substrate processing apparatus according to an embodiment of the disclosed subject matter;

FIG. 2 is a schematic side view of the substrate holding device according to one embodiment, showing a state in which a support body is located at an upper position;

FIG. 3 is a schematic side view of the substrate holding device, according to one embodiment showing a state in which a support body is at a supporting position;

FIG. 4 is a front view of the substrate holding device according to one embodiment, showing a state in which a support is located at an upper position;

FIG. 5 is a front view of the substrate holding device according to one embodiment, showing a state in which the support is located at a supporting position;

FIG. 6 is a perspective view of a support body according to one embodiment of the disclosed subject matter;

FIG. 7 is a plan view of the substrate holding device showing a state in which the predetermined substrate supporting position is changed in the embodiment;

FIG. 8 is a schematic side view of a substrate holding device showing a first modification of the embodiment;

FIG. 9 is a plan view of a substrate holding device showing a second modification of the embodiment; and

FIG. 10 is a plan view of a substrate holding device showing a third modification of the embodiment.

### DETAILED DESCRIPTION

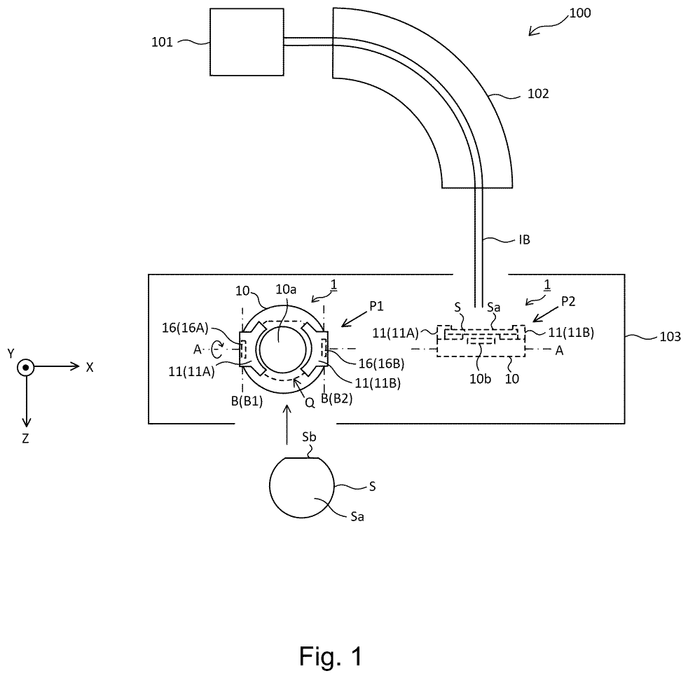

FIG. 1 shows a substrate holding device 1 and a substrate processing apparatus 100 using the substrate holding device 1 according to one embodiment. FIGS. 1 to 10 illustrate examples of the disclosed subject matter including various embodiments and show the various shapes, ratios of length dimensions, and ratios of scales of the respective components in the respective drawings which do not necessarily coincide with each other.

FIG. 1 is a schematic view illustrating a substrate holding device 1 and a substrate processing apparatus 100 that includes the substrate holding device 1 according to one embodiment of the disclosed subject matter.

As shown in FIG. 1, the substrate processing apparatus 100 can be an ion beam irradiation apparatus that irradiates a disk-shaped substrate S with an ion beam IB. The substrate S in this embodiment is a wafer. The substrate S has a surface Sa that is irradiated by an ion beam IB.

The ion beam irradiation apparatus shown in this embodiment is an example of a substrate processing apparatus 100 that uses the substrate holding device 1. The substrate processing apparatus 100 is not limited to the ion beam irradiation apparatus. The substrate holding device 1 is not limited to being used in an ion beam irradiation apparatus.

The wafer shown in this embodiment is an exemplary substrate S. However, it should be understood that substrate S is not limited to a wafer.

The substrate processing apparatus 100 can include an ion source 101 that generates plasma from a raw material gas, and a mass analysis magnet 102 that performs mass separation on an ion beam IB extracted from the ion source 101. The substrate processing apparatus 100 can include a processing chamber 103 in which the substrate S is irradiated with an ion beam IB. The ion beam IB that has passed through the mass analysis magnet 102 is guided to the processing chamber 103. A substrate holding device 1 for supporting the substrate S can be disposed in the processing chamber 103.

The X axis, the Y axis, and the Z axis shown in each of the Figures are orthogonal to each other. The Y axis is parallel to the height direction of the substrate holding device 1. Further, the Z-axis is parallel to the direction the ion beam IB travels as it is guided into the processing chamber 103. The substrate S can be reciprocated (moves) a plurality of times along the X axis so as to cross the ion beam IB in the processing chamber 103 while being supported by the substrate holding device 1.

The substrate holding device 1 includes a supporting base 10. The supporting base 10 has a circular support surface 10a on which the substrate S is placed. The supporting base 10 is configured to be rotatable within a predetermined range about a predetermined supporting base rotation axis A shown in FIG. 1.

The supporting base 10 is configured to rotate about the supporting base rotation axis A, which in turn changes the orientation of the support surface 10a. The supporting base 10 is configured to rotate about the supporting base rotation axis A to change from a loading posture P1 to a processing posture P2. The loading posture P1 is a posture when the substrate S is placed on the support surface 10a. The processing posture P2 is a posture when the predetermined processing is performed on the surface Sa. In this embodiment, the predetermined processing performed on the surface Sa is ion beam irradiation processing. The ion beam irradiation processing is, for example, an ion implantation or a surface treatment.

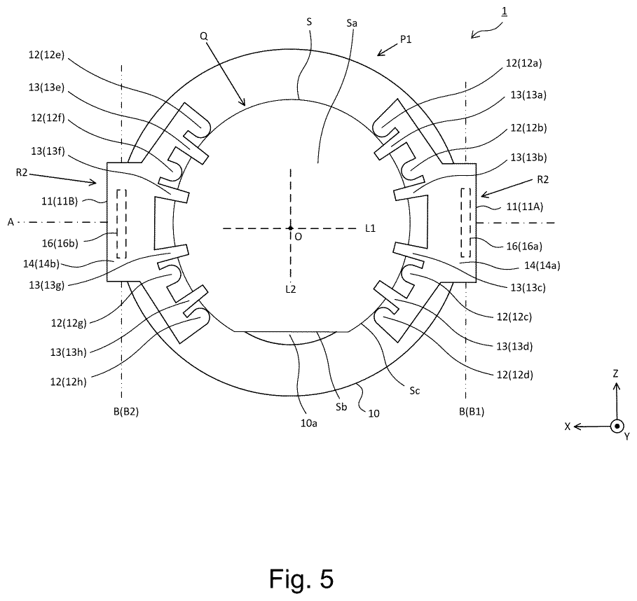

The substrate S can have a variety of different shapes and configurations. For example, the substrate S can have a disk shape. The substrate S can also have a flat surface Sb along its outer edge (see FIG. 5). Alternately, the substrate S can have a notch instead of the flat surface Sb.

The substrate S can be a plate material having a circular overall outline/outer edge surface. Rather than having a flat surface, the substrate S can be curved in its thickness direction.

FIG. 1 shows the supporting base 1 in a first posture P1 (loading posture) and a second posture P2 (processing posture). In the first posture P1, FIG. 1 shows the supporting base 10, as indicated by a solid line, configured to receive the substrate S. The supporting base 10, shown in solid lines in FIG. 1, is in the loading posture P1. After the substrate S is placed on the supporting base 10 in the loading posture P1, the supporting base 10 changes to the processing posture P2, also shown in FIG. 1. Thereafter, the substrate S crosses the ion beam IB while supported by the substrate holding device 1.

In FIG. 1, the supporting base 10 that traverses the ion beam IB while moving parallel to and rotating about the X-axis is indicated by a broken line. The supporting base 10, shown in broken lines in FIG. 1, is now oriented in the processing posture P2. As the supporting base 10 changes orientation from the loading posture P1 to the processing posture P2, the orientation of the surface Sa with respect to the ion beam IB changes.

The substrate holding device 1 includes a plurality of supporting bodies 11. The supporting body 11 can support the substrate S at a predetermined substrate support position Q on the support surface 10a when the supporting base 10 is in the processing posture P2. The number of the supporting bodies 11 is not limited to a specific number, but the substrate holding device 1 of the embodiment of FIG. 1 includes two supporting bodies 11.

When the predetermined processing is performed on the substrate S, the supporting base 10 is in the processing posture P2. In this state, the substrate S is supported at the substrate support position Q by the two supporting bodies 11.

The substrate S is continuously supported at the substrate support position Q by the two supporting bodies 11 while the surface Sa is irradiated with the ion beam IB. The substrate support position Q is a relative position with respect to the support surface 10a. In FIG. 1, the substrate support position Q in this embodiment is indicated by a broken line. Hereinafter, one of the two supporting bodies 11 may be referred to as a first supporting body 11A, and the other may be referred to as a second supporting body 11B.

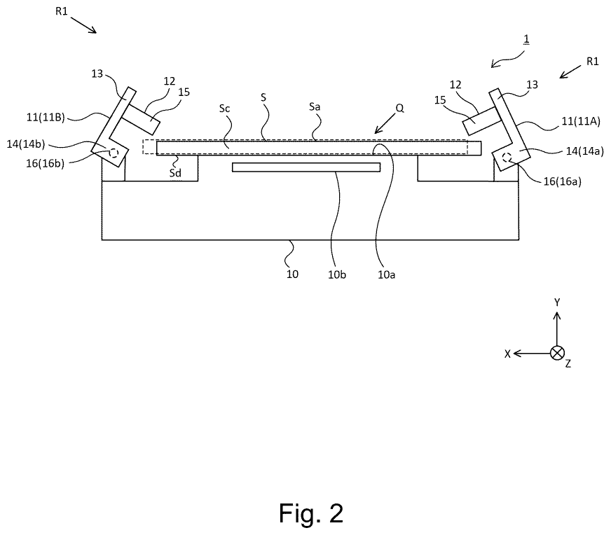

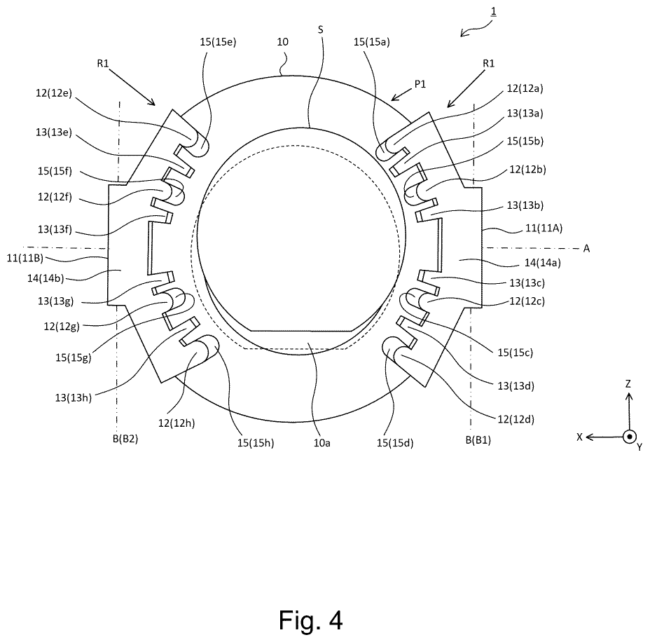

FIG. 2 is a schematic side view of the substrate holding device 1 showing a state when each supporting body 11 is at an upper or raised position R1. FIG. 4 is a schematic side view of the substrate holding device 1 showing a state when each supporting body 11 is at a support position R2.

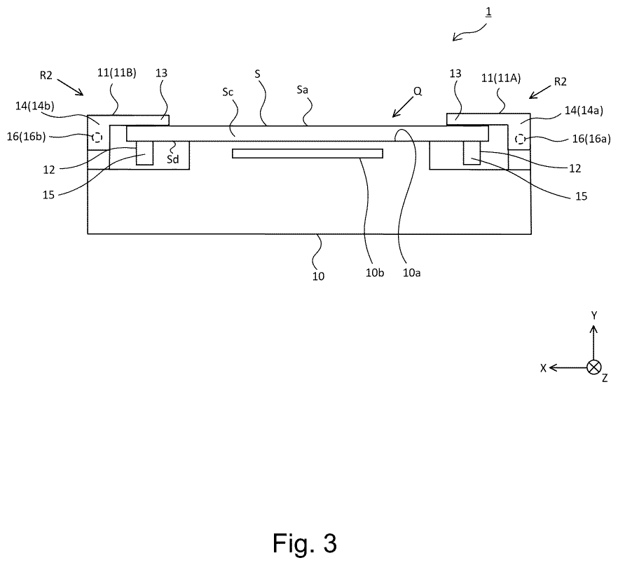

As shown in FIGS. 2 and 3, each supporting body 11 is attached to the supporting base 10 outside the support surface 10a. Each supporting body 11 can rotate about a rotation axis B (not shown) within a predetermined range. In this embodiment, the first supporting body 11A and the second supporting body 11B are disposed outside the support surface 10a and face each other with the support surface 10a interposed therebetween.

Each supporting body 11 includes a shaft member 16 disposed inside the supporting body 11. In FIGS. 2 and 3, the shaft member 16 is indicated by a broken line. A driving force generated by a motor (not shown) is transmitted to the shaft member 16.

This driving force to each shaft member 16 causes rotation of each supporting body 11 about the rotation axis B within a predetermined range. The rotation axis B is defined by the shaft member 16. In FIG. 1, the rotation axis B is indicated by a one dot chain line. The shaft members 16 are disposed parallel to the support surface 10a. That is, the rotation axes B are all parallel to the support surface 10a.

Hereinafter, the rotation axis B of the first supporting body 11A may be referred to as a first rotation axis B1, and the rotation axis B of the second supporting body 11B may be referred to as a second rotation axis B2. The shaft member 16 included in the first supporting body 11A may be referred to as a first shaft member 16a, and the shaft member 16 included in the second supporting body 11B may be referred to as a second shaft member 16b.

Each supporting body 11 can move from the upper position R1 shown in FIG. 2 to the support position R2 shown in FIG. 3 by rotating about the rotational axis B. The shaft members 16, that is, the first shaft member 16a and the second shaft member 16b are positioned outside the substrate S in the radial direction of the substrate S positioned at the substrate support position Q. Therefore, the rotation axis B of each supporting body 11 is located outside the substrate S in the radial direction of the substrate S positioned at the substrate support position Q.

Thus. each supporting body 11 can rotate about the rotation axis B within a predetermined range, and move from the upper position R1 to the support position R2.

The position at which each supporting body 11 starts rotating about the rotation axis B is not limited to the upper position R1. Each supporting body 11 can be configured to rotate starting from the lower position R2 towards the upper support position R1.

Each supporting body 11 has a plurality of support members 12 for supporting the substrate S at the predetermined substrate support position Q when each supporting body 11 is located at the support position R2. Each supporting body 11 also has a plurality of restriction members 13. The restriction members 13 are located along a top surface of each supporting body 11 and are positioned above the surface Sa to be treated in the thickness direction of the substrate S. The restriction members 13 regulate the motion of the substrate S when each supporting body 11 is at the support position R2 and the substrate S is positioned at the substrate support position Q. In this embodiment, the restriction members 13 serve to fix the substrate S in place when the supporting body 11 is in the support position R2.

Each of the support bodies 11 in this embodiment has four support members 12 in addition to the four restriction members 13 described above. In FIGS. 2 and 3, support members 12 and restriction members 13 are schematically shown. The number of the support members 12 and the number of the restriction members 13 included in each supporting body 11 are not limited to specific number shown in FIGS. 2 and 3. The number of the restriction members 13 and the positions where the restriction members 13 are disposed can be modified depending on the size, orientation and expected movement of the substrate S.

Each of the supporting bodies 11 also has a base portion 14 that connects a plurality of support members 12 and a plurality of restriction members 13. Each supporting body 11 in this embodiment is formed by integrally molding four support members 12, four restriction members 13, and a base portion 14. Hereinafter, the base portion 14 of the first supporting body 11A can be referred to as a first base portion 14a, and the base portion 14 of the second supporting body 11B can be referred to as a second base portion 14b. Each supporting body 11 can be assembled from, for example, the support member 12, the restriction member 13, and the base portion 14 which can be formed as individual components.

Each of the support members 12 in this embodiment has a columnar shape and has a height dimension larger than a thickness dimension of the substrate S. Further, each of the support members 12 has a contact surface 15 that can support the substrate S by contacting a side surface Sc of the substrate S positioned at the substrate support position Q when the supporting body 11 is positioned at the support position R2. In this embodiment, each supporting body 11 has four support members 12. Each supporting body 11 thus has four contact surfaces 15.

The substrate S is carried into the processing chamber 103 and placed on the support surface 10a by a robot or other automated system (not shown). At this time, the substrate S may be located at a position that deviates from the predetermined substrate support position Q. FIG. 2 shows an instance when the substrate S is placed at a position that deviates from a substrate support position Q as indicated by a broken line.

Even when the substrate S is placed at a position that deviates from the substrate support position Q, the substrate S is guided to the predetermined substrate support position Q by the movement of each supporting body 11 from the upper position R1 to the supporting position R2 while at least one contact surface 15 is in contact with a peripheral edge of the side surface Sc or a back surface Sd of the substrate S.

The restriction member 13 also regulates the movement of the substrate S positioned at the substrate support position Q. Thus, the supporting body 11, including the restriction member 13, can engage the substrate S so that it is positioned in the support position Q.

As shown in FIG. 3, each of the restriction members 13 in this embodiment is configured to contact the surface Sa of the substrate S when the supporting body 11 is located at the support position R2 and positioned above the surface Sa. In addition, in this embodiment, each restriction member 13 is only in contact with the surface Sa, and is not intended to apply a pressing force for pressing the substrate S toward the support surface 10a. The substrate holding device 1 can be configured such that at least one restriction member 13 applies a pressing force to the substrate S.

As shown in FIG. 2, when each supporting body 11 is located at the upper position R1, each contact surface 15 is located above the support surface 10a. Thus, at the upper position R1, the contact surface 15 is above and not in contact with the support surface 10a. As the supporting body 11 moves from upper position R1 to support position R2, the contact surface 15 comes into contact with the substrate S. Furthermore, when the supporting body 11 is located at the upper position R1, the entire region of the contact surface 15 does not need to be above the support surface 10a.

The two supporting bodies 11 rotate about the predetermined rotation axis B, respectively, and operate such that the contact surfaces 15 move from the upper position R1 toward the support surface 10a side, and reach the support position R2 where the substrate S is supported. With the operation of each supporting body 11, each support member 12 also operates to move from the upper side of the substrate S placed on the support surface 10a to the lower side of substrate S.

While the two supporting bodies 11 move from the upper position R1 to the support position R2, at least one contact surface 15 guides the substrate S to the substrate support position Q while contacting the substrate S placed at a position that deviated from the predetermined substrate support position Q on the support surface 10a.

If the support member 12 moves from the lower side of the substrate S placed on the support surface 10a toward the substrate S, it is assumed that the substrate S is lifted by at least one contact surface 15 if the substrate S is placed at a position deviated from the substrate support position Q. In this case, it is assumed that the substrate S is finally lifted by the at least one contact surface 15 and supported by the supporting body 11 so that a part of the substrate S is separated from the support surface 10a. That is, when the contact surface 15 of the supporting body 11 moves from the lower side to the upper side of the support surface 10a, the substrate S is not supported at the predetermined substrate support position Q.

In contrast, in this embodiment, as the two support bodies 11 move from the upper position R1 to the support position R2, the contact surfaces 15 move from the upper side of the substrate S placed on the support surface 10a toward the lower side of substrate S. Therefore, even when the substrate S is placed at a position deviated from the substrate support position Q, the substrate holding device 1 can reliably guide the substrate S to the substrate support position Q without lifting the substrate S.

In the substrate processing apparatus 100 using the holding device 1, the plurality of supporting bodies 11 support the substrate S at the predetermined substrate support position Q even when the supporting base 10 is in the processing posture P2. That is, even when the substrate S is placed at a position deviated from the substrate support position Q, the substrate processing apparatus 100 can perform processing when the substrate S is supported at the substrate support position Q by the plurality of supporting bodies 11 guiding and supporting the substrate S to the substrate support position Q to arrive at the processing posture P2.

As shown in FIGS. 2 and 3, the holding device 1 includes electrodes 10b which are disposed inside the supporting base 10 and electrostatically adsorb the substrate S to the supporting surface 10a. That is, the supporting base 10 in this embodiment is configured as an electrostatic chuck that electrostatically adsorbs the substrate S to the support surface 10a.

As shown in FIG. 1, in the substrate processing apparatus 100 of this embodiment, the substrate S is first carried into the processing chamber 103 from the outside, and then placed on the support surface 10a of the supporting base 10 at the loading posture P1 by a robot or other automated system (not shown). At this time, each supporting body 11 is located at the upper position R1 shown in FIG. 2, and the substrate S is placed on the support surface 10a without contacting each supporting body 11.

Thereafter, each supporting body 11 can rotate about the predetermined rotation axis B to move to the support position R2 shown in FIG. 3, and the substrate S is supported at the substrate support position Q by the supporting body 11.

When the substrate S is placed on the support surface 10a by a robot or other automated system (not shown), the substrate S may be placed at a position that deviates from a predetermined substrate support position Q. Even in this case, as each supporting body 11 moves from the upper position R1 to the support position R2, at least one contact surface 15 moves while being in contact with the substrate S, and guides the substrate S to the predetermined substrate support position Q.

In other words, the substrate S placed at a position that deviates from the predetermined substrate support position Q moves on the support surface 10a while being pressed by at least one contact surface 15, and is guided to the substrate support position Q. More specifically, the contact surface 15 of at least one support member 12 moves so as to push the substrate S while contacting the peripheral edge of the side surface Sc or the back surface Sd of the substrate S, and guides the substrate S to the predetermined substrate support position Q.

Further, since each of the restricting members 13 in this embodiment is integrated with the supporting body 11, each of the restricting members 13 also rotates about the rotation axis B as the supporting body 11 rotates about the rotation axis B. Therefore, each restriction member 13 is positioned above the surface Sa as each supporting body 11 reaches the support position R2.

In certain embodiments, the restriction member 13 does not need to be integrated with the supporting body 11. The restriction member 13 may operate independently of the supporting body 11. In this case, the holding device 1 operates such that the restriction member 13 is positioned above the surface Sa at the same time as each supporting body 11 reaches the support position R2 or after each supporting body 11 reaches the support position R2.

If the substrate S is supported when placed at a position that deviates from the substrate support position Q, the restriction member 13 can be formed in a relatively large shape in order to regulate the movement of the substrate S regardless of the position of the substrate S.

The restriction member 13 of this embodiment does not need to be configured in consideration of the fact that the substrate S may be disposed at a position that deviates from the predetermined substrate support position Q. The area of the substrate S covered by the restriction member 13 is relatively small. Accordingly, for example, while the substrate processing apparatus 100 performs the process of irradiating the substrate S with the ion beam IB, the region of the surface Sa, which is not processed due to the ion beam IB being blocked by the restriction member 13, is relatively small.

After the substrate S is supported at the substrate support position Q by the supporting base 11, a voltage is applied to the electrodes 10b, and the substrate S is electrostatically attracted to the supporting surface 10a. That is, the substrate S is supported at the substrate support position Q by electrical forces generated by applying the voltage to the electrodes 10b in addition to the two supporting bodies 11.

After the substrate S is supported at the substrate support position Q, as shown in FIG. 1, the supporting base 10 rotates about the supporting base rotation axis A towards the processing posture P2, and the surface Sa is directed towards the ion beam IB. Thereafter, the substrate holding device 1 supporting the substrate S in the processing chamber 103 reciprocates (moves) so as to cross the ion beam IB, and the ion beam IB irradiates the surface Sa.

When the ion beam IB irradiates substantially the entire region of the surface Sa and the process of irradiating the substrate S is completed, the supporting base 10 is rotated around the supporting base rotation axis A and returns to the loading posture P1. Then, the electrostatic adsorption of the substrate S is released by releasing the application of the voltage to the electrodes 10b. Thereafter, the pair of support bodies 11 moves to the upper position R1 again, and the support of the substrate S by the substrate holding device 1 is released. Thereafter, the substrate S is lifted by a robot or other automated system (not shown) to be separated from the support surface 10a, and is carried out of the processing chamber 103.

When application of voltage to the electrodes 10b is released and the electrostatic adsorption to the substrate S is released, the substrate S may move so as to separate from the support surface 10a. In this case, it is assumed that the substrate S is detached from the support surface 10a or the substrate S is moved to a position significantly away from (or deviated from) the substrate support position Q. When such a situation occurs, the robot or other automated system (not shown) cannot lift and transport the processed substrate S. In this case, operation of the substrate processing apparatus 100 is stopped.

In contrast, the substrate holding device 1 can include the restriction member 13 that restricts movement of the substrate S. Therefore, even when the substrate S tends to separate from the support surface 10a as described above, the restriction member 13 restricts the substrate S from moving. That is, when application of voltage to the electrodes 10b is released, the substrate S is prevented from falling off from the support surface 10a or from being greatly displaced from the substrate support position Q.

Each of the restriction members 13 can be configured to prevent the substrate S from being significantly displaced from the predetermined substrate support position Q due to the movement and separation of the substrate S from the support surface 10a. The restriction member 13 may not be in contact with the surface Sa of the substrate S when the supporting body 11 is located at the support position R2. The restriction member 13 may be positioned above the surface Sa in the thickness direction of the substrate S.

The substrate holding device 1 of this embodiment can support the substrate S at the substrate support position Q only through the two supporting bodies 11 even when the supporting base 10 is positioned at the processing posture P2. In this instance, the surface Sa of the substrate S is directed to the ion beam IB.

As a result, even when no voltage is applied to the electrodes 10b, the substrate S is supported at the substrate support position Q only by the two supporting bodies 11. Therefore, the substrate holding device is still able to support the substrate S even if supporting base 10 does not include an electrostatic chuck. Since the supporting base 10, in certain embodiments, includes an electrostatic chuck, the substrate S is more firmly held at the substrate support position Q.

When the substrate holding device 1 does not include the electrodes 10b, that is, when the supporting base 10 is not configured as an electrostatic chuck device, the above-described separation of the substrate S does not occur. Therefore, when the supporting base 10 does not include an electrostatic chuck device, the substrate holding device 1 may not include the restriction member 13. Further, even when the supporting base 10 is configured as an electrostatic chuck, the substrate holding device 1 may not include the restriction member 13 when the above-described separation of the substrate S is not expected.

Even when the substrate holding device 1 does not include the electrodes 10b, the restriction member 13 may be provided for the purpose of more firmly holding the substrate S at the substrate support position Q. In this case, the restriction member 13 is configured to contact the surface Sa of the substrate S located at the substrate support position Q.

FIG. 4 is a plan view of the substrate holding device 1 showing a state when the two supporting bodies 11 are located at the upper position R1.

FIG. 5 is a plan view of the substrate holding device 1 showing a state when the two supporting bodies 11 are located at the supporting position R2. The supporting base 10 shown in FIGS. 4 and 5 is in the loading posture P1.

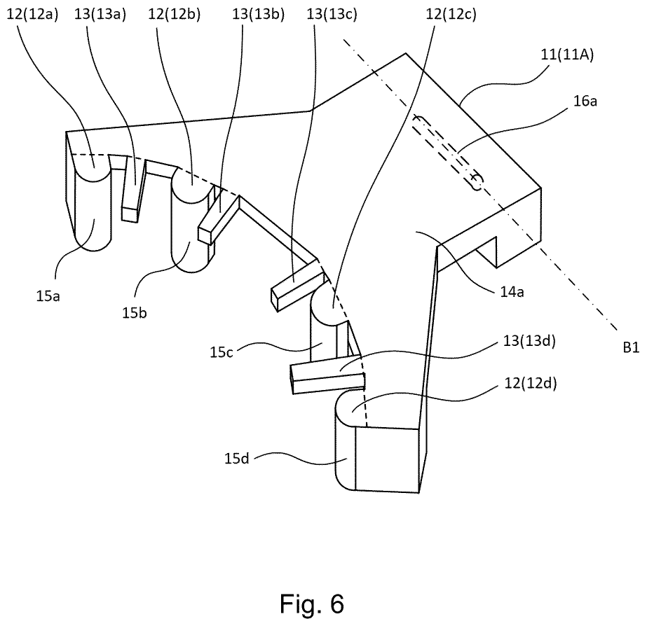

FIG. 6 is a perspective view of the first supporting body 11A according to one embodiment. Since the second supporting body 11B in this embodiment has a configuration that is linearly symmetrical to the first supporting body 11A, a perspective view of the second supporting body 11B is omitted.

As shown in FIGS. 4 and 5, the first supporting body 11A and the second supporting body 11B can each have four support members 12, four restriction members 13, and a base portion 14 connecting the support members 12 and the restriction members 13.

Hereinafter, the four support members 12 included in the first supporting body 11A can be referred to as support members 12a to 12d, respectively, and the four support members 12 included in the second supporting body 11B can be referred to as support members 12e to 12h, respectively. The four restriction members 13 included in the first supporting body 11A are referred to as restriction members 13a to 13d, and the four restriction members 13 included in the second supporting body 11B are referred to as restriction members 13e to 13h.

FIG. 5 shows a first straight line L1 indicated by a broken line which passes through the center O of the substrate S when the substrate is placed at the substrate supporting position Q and is horizontally parallel when the supporting base 10 is in the processing posture P2. Thus, the first straight line L1 is parallel to the supporting base rotation axis A and the X-axis.

FIG. 5 also shows a second straight line L2 indicated by a broken line which passes through the center O of the substrate S when the substrate is placed at the substrate supporting position Q and perpendicular to the first straight line L1.

The substrate S can be divided into four regions by the first straight line L1 and the second straight line L2. In this embodiment, when the supporting base 10 is moved to the processing posture P2, the flat surface Sb of the substrate S is positioned downward. In this embodiment, in the region partitioned by the first straight line L1, the upper side of the substrate S when the supporting base 10 is in the processing posture P2 is defined as the portion of the substrate S that is above the dashed line L1 (see FIG. 5). In addition, in the region partitioned by the first straight line L1, the lower side of the substrate S when the supporting base 10 is in the processing posture P2 is defined as the portion of the substrate S that is below the dashed line L1 (see FIG. 5). In addition, in the region partitioned by the second straight line L2 in FIG. 5, the portion of the substrate S to the right of line L2 is referred to as the right side of the substrate S, and the portion of the substrate to the left of line L2 is referred to as the left side of the substrate S for convenience.

As shown in FIG. 5, the support member 12a and the support member 12b of the first support body 12A support the side surface Sc in the upper and right region of the substrate S. Further, the support member 12c and the support member 12d of the first support body 11A support the side surface Sc in the lower and right region of the substrate S.

The support member 12e and the support member 12f of the second support body 11B support the side surface Sc in the upper and left region of the substrate S. The support member 12g and the support member 12h of the second support body 11B support the side surface Sc in the lower and left region of the substrate S.

The restriction member 13a and the restriction member 13b of the first support body 11A are positioned above the surface Sa in the upper and right region of the substrate S. Further, the restriction member 13c and the restriction member 13d of the first support body 11A are positioned above the surface Sa in the lower right region of the substrate S.

The restriction member 13e and the restriction member 13f of the second support body 11B are positioned above the surface Sa in the upper and left region of the substrate S. Further, the restriction member 13g and the restriction member 13h of the second support body 11B are positioned above the surface Sa in the lower and left region of the substrate S.

As described above, in this embodiment, two support members 12 and two restriction members 13 are positioned in each of four regions of the substrate S divided by the first straight line L1 and the second straight line L2.

As shown in FIG. 6, the support members 12a to 12h have contact surfaces 15a to 15h, respectively, which can contact the side surface Sc to support the substrate S. The contact surfaces 15a to 15h each form a curved surface bulging toward the center O of the substrate S which can support the substrate S shown in FIG. 5. The contact surfaces 15a to 15h forming a curved surface includes the contact surfaces 15a to 15h forming a spherical or cylindrical surface with a partially circular cross-section.

Since the contact surfaces 15a to 15h are curved surfaces, the substrate holding device 1 can smoothly guide the substrate S to the predetermined substrate support position Q even when the substrate S is placed at a position that deviates from the predetermined substrate support position Q of the surface Sa.

FIG. 4 the substrate S is placed at a position displaced from the predetermined substrate support position Q obliquely upward to the right in the drawing. When the first supporting body 11A and the second supporting body 11B are rotated and moved from the upper position R1 toward the support position R2 from the position shown in FIG. 4, the contact surface 12a of the support member 15a closest to the substrate S first comes into contact with the peripheral edge of the back surface Sd or the side surface Sc. Then, as the first supporting body 11A rotates about the first rotation axis B1, the substrate S is pushed by the contact surface 15a and moves on the support surface 10a toward the lower left direction with respect to the paper surface of the drawing of FIG. 4.

Thereafter, as the first support 11A and the second support 11B rotate, the substrate S comes into contact with the contact surface 15e and is then pushed by the contact surface 15a and the contact surface 15e to move downward in the negative “Z” direction as viewed with respect to the drawing of FIG. 4. Then, the substrate S is guided while being in contact with any of the other contact surfaces 15b to 15d and the contact surfaces 15f to 15h, and is finally positioned at the predetermined substrate support position Q.

As described above, in the substrate holding device 1 of this embodiment, the contact surfaces 12a to 12h of the supporting members 15a to 15h push the side surface Sc or the peripheral edge of the back surface Sd as the first supporting body 11A and the second supporting body 11B rotate, thereby guiding the substrate S to the predetermined substrate support position Q.

The first supporting body 11A and the second supporting body 11B of this embodiment respectively have four support members 12a to 12d and support members 12e to 12 h. The number of support members 12 included in the first support and the second support is not limited thereto. In addition, the first supporting body 11A and the second supporting body 11B respectively include four restriction members 13a to 13d and four restriction members 13e to 13 h. The number of restriction members 13 included in the first support body 11A and the second support body 11b is not limited thereto.

As described above with respect to FIG. 5, the substrate S is divided into four regions by a first straight line L1 passing through the center O of the substrate S placed at the substrate support position Q and parallel to the horizontal direction and a second straight line L1 passing through the center O of the substrate S and perpendicular to the first straight line L2. In the substrate holding device 1 of this embodiment, two contact surfaces 15 come into contact with the substrate S in each of the four regions to support the substrate S.

With this configuration, the substrate holding device 1 can guide the substrate S to the substrate support position Q and support the substrate S at the substrate support position Q even when the substrate S is placed on the supporting surface 10a deviated from the predetermined substrate support position Q in any direction.

In order to guide the substrate S to the substrate support position Q and support the substrate S, the substrate holding device 1 may be configured such that at least one contact surface 15 comes into contact with the substrate S to support the substrate S in each of the four regions. That is, at least one support member 12 may be positioned in each of the four regions.

The substrate holding device 1 of this embodiment is also configured such that two contact surfaces 15 contact the substrate S in each of the four regions of the substrate S, assuming that the predetermined substrate support position Q is changed. That is, in the substrate holding device 1 of this embodiment, two supporting members 12 are positioned in each of the four regions.

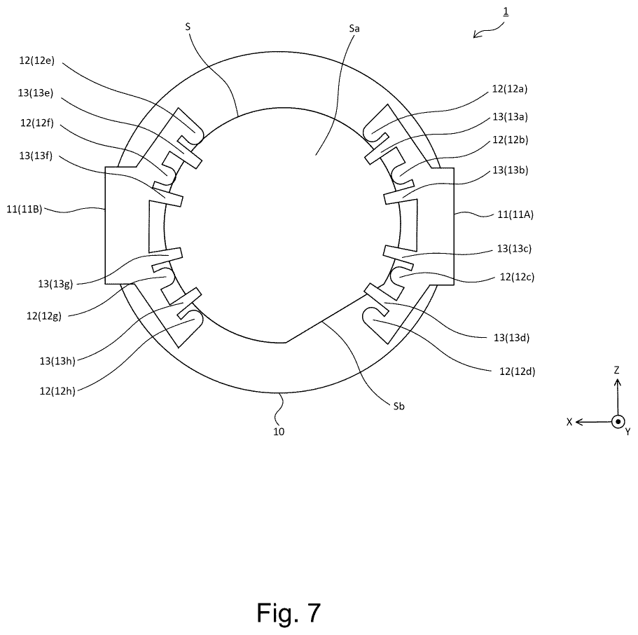

FIG. 7 is a plan view of the substrate holding device 1, illustrating an example of a change in the predetermined substrate support position Q. In FIG. 7 the substrate support position Q is changed and the oriental surface Sb of the substrate S is positioned at a position facing the support member 12d.

In this case, the contact surface 15d of the support member 12d cannot contact the substrate S. Therefore, if the first supporting body 11A does not include the support member 12c, the substrate S is not guided and supported in the region on the right side and the lower side of the substrate S. In addition, when the supporting base 10 is rotated in this state and the processing posture P2 is reached, the substrate S may fall from the supporting base 10.

In this embodiment, the support member 12c is positioned in addition to the support member 12d in the region on the right side and the lower side of the substrate S. Therefore, even when the substrate support position Q is changed as described above, the substrate S can be reliably guided to the substrate support position Q, and the substrate S can be reliably supported even when the supporting base 10 is in the processing posture P2.

Thus, the number and arrangement of the support members 12 of the supporting body 11 may be appropriately set according to the position of the flat surface Sb or the notch of the substrate S at the substrate support position Q.

If the position of the substrate support position Q is not changed, the substrate holding device 1 may support the substrate S by one contact surface 15 contacting the substrate S in each of the four regions. That is, the substrate holding device 1 may be configured such that at least one support member 12 supports the substrate S in each of the four regions.

In contrast, when the position of the substrate support position Q is changed, the substrate holding device 1 can be configured such that a plurality of contact surfaces 15 comes into contact with the substrate S in each of the four regions. The substrate holding device 1 can be configured such that the plurality of contact surfaces 15 comes into contact with the substrate S in at least one of the four regions according to the position of the flat surface Sb or the notch located at the changed substrate support position Q.

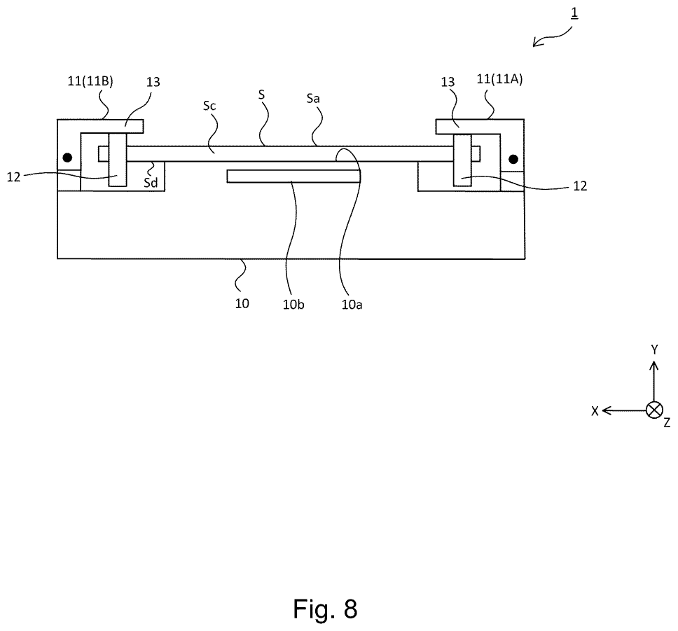

FIG. 8 is a schematic side view of the substrate holding device 1, showing a first modification of the substrate holding device 1. In this modification, each restriction member 13 is separated from the surface Sa whereby each supporting body 11 is located at the support position R2 and each restriction member 13 is located above the surface Sa.

The substrate S may separate when the application of voltage to the electrodes 10b is released. Even in such a case, since the restriction members 13a to 13h are above the substrate S, the motion of the substrate S is regulated, and for example, the substrate S is prevented from being detached from the support surface 10a.

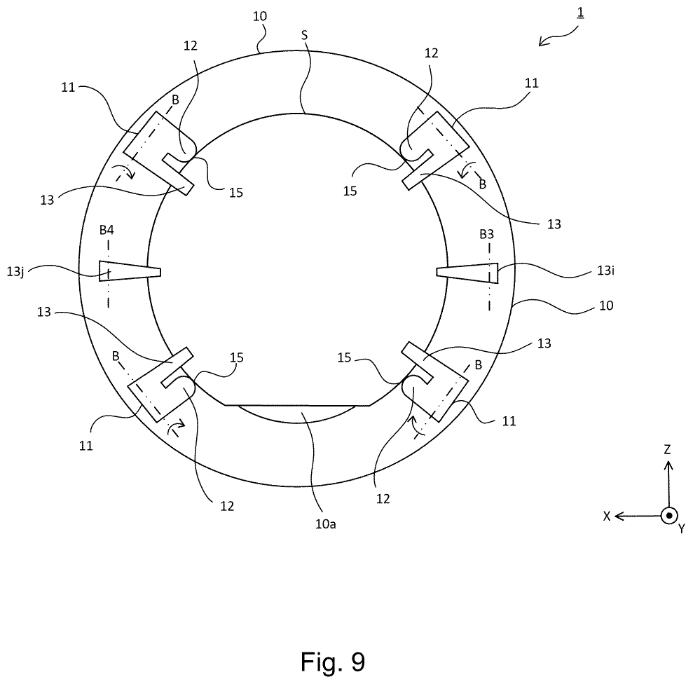

FIG. 9 is a plan view of the substrate holding device 1, showing a second modification of the substrate holding device 1. As shown in FIG. 9, the substrate holding device 1 in the second modification includes four supporting bodies 11. In addition, each supporting body 11 is integrally configured with one support member 12 having one contact surface 15 and one restriction member 13.

The substrate holding device 1 in the second modification includes two restriction members 13i and 13j that operate independently, separately from the respective supporting bodies 11. The two restriction members 13i and 13j are both fixed to the supporting base 10. The two restriction members 13i and 13j rotate about the rotation axes B3 and B4 parallel to the support surface 10a, respectively.

Both of the two restriction members 13i and 13j are operated so as to be positioned above the surface Sa at the same time as each supporting body 11 reaches the support position R2 or immediately after each supporting body 11 reaches the support position R2.

The number of the plurality of supporting bodies 11 included in the substrate holding device 1 is not limited to a specific number. The number of support members 12 and the number of contact surfaces 15 provided in each support 11 are also not limited to a specific number. The restriction member 13 does not need to be formed integrally with the supporting body 11. The restriction member 13 may operate independently of the supporting body 11.

Further, the substrate holding device 1 is not limited to the configuration in which at least one support member 12 is positioned in each of the four regions of the substrate S divided by the first straight line L1 and the second straight line L2 when the supporting body 11 is positioned at the supporting position R2.

In order to guide and support the substrate S at the predetermined substrate support position Q, the plurality of contact surfaces 15 may be arranged such that the center O of the substrate S placed at the substrate support position Q is included in a triangular region formed by three points selected from a plurality of points at which each contact surface 15 and the side surface Sc are in contact with each other.

In other words, if three support members 12 each having one contact surface 15 are arranged such that the center O of the substrate S is included in a triangular region formed by connecting three points at which each support member 12 and the side surface Sc are in contact with each other, the substrate S is guided to and supported at the predetermined substrate support position Q.

Therefore, when the position of the flat surface Sb or the notch is where the substrate S is placed at the predetermined substrate support position Q, that is, when the position of the flat surface Sb or the notch is not changed, the substrate holding device 1 may include at least three supporting members 12.

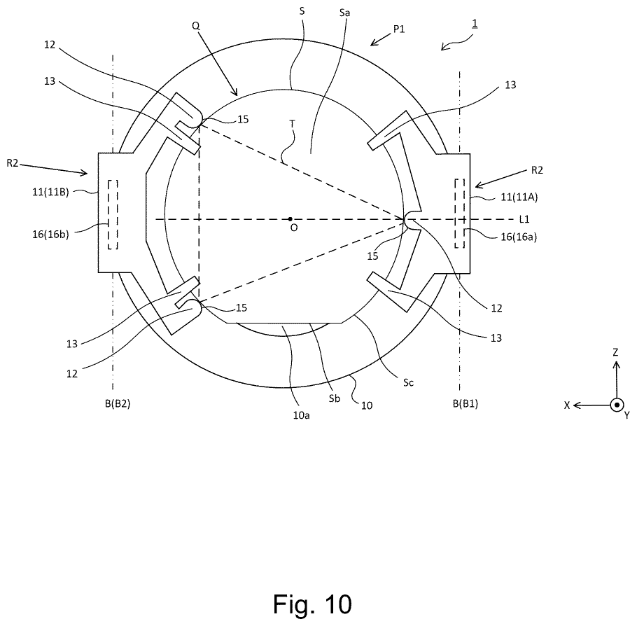

FIG. 10 is a plan view of the substrate holding device 1, illustrating a third modification of the substrate holding device 1. In the substrate holding device 1 according to the third modification, the number and positions of the supporting members 12 and the restriction members 13 included in the first supporting body 11A and the second supporting body 11B are changed.

As described above, when the position of the flat surface Sb of the substrate S is positioned at the predetermined substrate support position Q and is not changed, the substrate holding device 1 may include at least three supporting members 12. In the substrate holding device 1 of the third modification, the first supporting body 11A includes one support member 12, and the second supporting body 11B includes two support members 12.

As shown in FIG. 10, the support member 12 included in the first supporting body 11A is in contact with the side surface S on the first straight line L1. The two support members 12 of the second supporting body 11B are in contact with the side surface Sc at positions symmetrical with respect to the first straight line L1. As an example, in such an arrangement, the center O of the substrate S is located within a region of a triangle T formed by connecting points at which the three support members 12 included in the first supporting body 11A and the second supporting body 11B and the side surface Sc of the substrate S are in contact with each other. Therefore, the substrate S may be guided to and supported at a predetermined substrate support position Q by the support member 12.

Thus, the substrate holding device 1 may have three or more contact surfaces 15, and these contact surfaces 15 may be configured such that the center O of the substrate S is present in any triangular region formed by connecting three points at which each contact surface 15 and the side surface Sc are in contact with each other.

It should be understood that embodiments are not limited to the various embodiments described above with reference to the drawings, but various other changes and modifications may be made therein without departing from the spirit and scope thereof as set forth in appended claims.

What is claimed is:

1. A substrate holding device comprising:
a supporting base including a support surface configured to receive a substrate, the supporting base further configured to change from a loading posture to a processing posture by rotating the supporting base to change a direction of the support surface; and
a plurality of support bodies, each support body having a support member and at least one contact surface, wherein
each support body is configured to rotate about a predetermined rotation axis, causing each support body to move from an upper position where the contact surface is located above the support surface to a support position where the contact surface is located closer to the support surface than when in the upper position, and
the at least one contact surface is configured to guide the substrate to a substrate support position while contacting the substrate when placed at a position deviated from the substrate support position on the support surface.

2. The substrate holding device according to claim 1, wherein the at least one contact surface includes contact surfaces arranged such that a center of the substrate when placed at the substrate supporting position is present within any triangular region formed by connecting three points at which each contact surface and a side surface of the substrate are in contact with each other.

3. The substrate holding device according to claim 1, wherein the at least one contact surface includes a first contact surface, a second contact surface, a third contact surface, and a fourth contact surface, and the first contact surface is configured to be in contact with the substrate in a first of four regions, the second contact surface is configured to be in contact with the substrate in a second of the four regions, the third contact surface is configured to be in contact with the substrate in a third of the four regions, and the fourth contact surface is configured to be in contact with the substrate in a fourth of the four regions, wherein each of the four regions is separated from each other by a first straight line passing through a center of the substrate placed at the substrate supporting position and parallel to a horizontal direction when the supporting base is in the processing posture and a second straight line passing through the center and perpendicular to the first straight line.

4. The substrate holding device according to claim 3, wherein when the substrate has a flat edge surface a plurality of contact surfaces of the at least one contact surface is in contact with the substrate in at least one of the four regions.

5. The substrate holding device according to claim 1, further comprising at least one restriction member positioned above a surface to be processed of the substrate when the substrate is received by the support surface, and is configured to restrict movement of the substrate when the substrate is positioned at the support surface.

6. The substrate holding device according to claim 5, wherein the restriction member is positioned above the surface to be processed of the substrate when the plurality of support members reaches the support position and after the plurality of support members reach the support position.

7. The substrate holding device according to claim 5, wherein the restriction member is in contact with the surface to be processed of the substrate when the restriction member is positioned above the surface to be processed of the substrate.

8. The substrate holding device according to claim 5, wherein the restriction member is separated from the surface to be processed of the substrate when the restriction member is positioned above the surface to be processed of the substrate.

9. The substrate holding device according to claim 5, wherein the supporting base is configured as an electrostatic chuck configured to electrostatically adsorb the substrate to the support surface.

10. The substrate holding device according to claim 1, wherein the at least one contact surface is configured to contact a side surface of the substrate when a respective one of the plurality of support members is in the support position.

11. The substrate holding device according to claim 1, wherein each support body includes a restriction member extending from a top surface of the support body.

12. The substrate holding device according to claim 1, wherein each support body includes a shaft member configured to receive a driving force that causes each support body to rotate from the upper position to the support position.

13. The substrate holding device according to claim 1, wherein the at least one contact surface is configured to guide the substrate to a predetermined substrate support position.

14. The substrate holding device according to claim 1, wherein the at least one contact surface is a curved surface.

15. A substrate holding device, comprising:
a supporting base including a support surface configured to receive a substrate, the supporting base further configured to change from a loading posture to a processing posture; and
a plurality of support bodies, each support body having a support member having at least one contact surface, wherein
the plurality of support bodies includes at least three contact surfaces separate from each other and located about a center of a substrate when the substrate is received on the supporting base,
each of the plurality of support bodies is configured to rotate about a rotation axis, such that each of the plurality of support bodies is movable from an upper position where the at least one contact surface is located above the support surface to a support position where the at least one contact surface is located closer to the support surface than when in the upper position.

16. The substrate holding device of claim 15, wherein
a first of the plurality of support bodies includes a first one of the at least three contact surfaces and a second one of the at least three contact surfaces, and
a second of the plurality of support bodies includes a third one of the at least three contact surfaces.

17. The substrate holding device of claim 16, wherein
the second of the plurality of support bodies includes a fourth one of the at least three contact surfaces.

18. The substrate holding device of claim 15, wherein
the support member extends in a first direction from a respective one of the plurality of support bodies, and the respective one of the plurality of support bodies includes a restriction member extending a second direction substantially perpendicular to the first direction.

19. The substrate holding device of claim 18, wherein the at least one contact surface is a semicircular cylindrical surface having a central axis extending parallel with the first direction.

20. The substrate holding device of claim 15, further comprising:
a restriction member that extends from a peripheral portion of the supporting base to a first location spaced a first distance from a center of the support surface such that the restriction member is configured to hold a top surface of the substrate when the substrate is received on the support surface, wherein
the at least one contact surface is located at a second distance from the center of the support surface greater than the first distance when the support body associated with the at least one contact surface is in the support position such that the at least one contact surface is configured to contact a side surface of the substrate when the substrate is received on the support surface and the at least one contact surface is in the support position.
